(19) United States
(12) Patent Application Publication
(10) Pub. No.: US 2024/0349624 A1
(43) Pub. Date: Oct. 17, 2024

(54) SPIN-ORBIT RECTIFIER FOR WEAK RADIO FREQUENCY ENERGY HARVESTING

(71) Applicant: THE REGENTS OF THE UNIVERSITY OF CALIFORNIA, Oakland, CA (US)

(72) Inventors: Eli Yablonovitch, Oakland, CA (US); Sayeef Salahuddin, Walnut Creek, CA (US); Shehrin Sayed, Fremont, CA (US)

(21) Appl. No.: 18/034,489

(22) PCT Filed: Oct. 28, 2021
(86) PCT No.: PCT/US2021/057086

§ 371 Date: Apr. 28, 2023

Related U.S. Application Data
(60) Provisional application No. 63/107,215, filed on Oct. 29, 2020.

(51) Int. Cl. H10N 52/00; H01L 23/66; H10N 50/85; H10N 52/80; H10N 59/00

(52) U.S. Cl. CPC H10N 52/101; H01L 23/66; H10N 50/85; H10N 52/80; H10N 59/00; H01L 2223/6677

(57) ABSTRACT

A rectifier device, has a Hall layer comprising a layer of a Hall material, and a spin-orbit layer adjacent the Hall layer. The spin-orbit layer has a spin-orbit material having a first surface and a second surface, a ferromagnet adjacent the spin-orbit material, and oxide on the outer surfaces of the spin-orbit layer. A rectifying system has an array of the above rectifying devices having a number, K, of parallel branches, each branch having N devices, branch electrical connections between corresponding devices in each of the parallel branches, and device electrical connection between devices in each parallel branch.

### CROSS REFERENCE TO RELATED APPLICATION

This application claims priority to and the benefit of U.S. Provisional Application No. 63/107,215 filed Oct. 29, 2020, which is incorporated herein in its entirety.

### STATEMENT REGARDING FEDERALLY SPONSORED RESEARCH AND DEVELOPMENT

This invention was made with Government support under Contract 0939514 awarded by the National Science Foundation. The Government has certain rights in this invention.

### TECHNICAL FIELD

This disclosure relates to rectifiers and detectors of radio frequency signals, more particularly to rectifiers and detectors using the Hall effect and spin-orbit torque.

### BACKGROUND

Scavenging of the ambient radio-frequency (RF) signals is of great current interest, especially in the context of the Internet of Things, device miniaturization, and 3D integration, where integration of self-powered devices will be highly beneficial. However, development of such technologies is severely limited by the conventional semiconductor rectifiers, especially for scavenging from the weak RF signals because of the thermal voltage limit, high-resistance p-n junctions, etc. Most of the conventional technologies become highly inefficient when the input RF power is in the order of ˜100 μW.

Most semiconductor rectifying technologies are significantly inefficient below a few mW of input RF power. Few Schottky diode-based technologies can rectify in the regime of ˜100 μW. A few CMOS based rectifiers have been proposed to have 86% efficiency from input RF power in the order of ˜100 μW. Almost all semiconductor diode based rectifying technologies are limited by the thermal voltage even in the ideal limit. Heterojunction backward tunnel diodes promise to operate approximately two times lower than the thermal voltage limit and has shown rectification from much lower input RF power. One approach has demonstrated an efficiency of 18% from an input RF power in the order of 1 μW while an efficiency of 3% from an input RF power in the order of 100 nW.

Some solutions being investigated include some new materials to go beyond these limitations, including ballistic graphene nanorectifiers, and magnetic tunnel junction based spin-diodes, etc. These new technologies currently have very low RF-to-DC power conversion efficiencies and do not operate well in the weak RF limit. Spin-diodes are growing attention for RF detection, because under an external bias these devices are able to produce large DC voltage for a given RF power, in the order of >10⁴ μV/μW [6−9], while conventional Schottky diodes are limited to <10³ μV/μW.

However, these devices work in the μW input power region and the requirement of an external bias is not attractive for energy harvesting. Their no-bias sensitivity is in the order of ˜10² μV/μW and conversion efficiency is <0.1% from an RF power ˜10 μW. Previously, a proposal of potentiometric spin voltage measurements-based rectifier that uses spin-orbit torque materials estimated low efficiency in an all-metallic geometry.

### BRIEF DESCRIPTION OF THE DRAWINGS

FIG. 1 shows embodiments of a rectifier using Hall material.

FIG. 2 shows embodiments of a spin-orbit rectifier using a Hall material.

FIG. 3 shows an alternative embodiment of a spin-orbit rectifier using a Hall material.

FIGS. 4-7 show results of a circuit analysis of a spin-orbit rectifier using a Hall material.

FIG. 8 shows a representative circuit used to produce the results of FIGS. 4-7.

FIG. 9 shows an embodiment of an array of spin-orbit rectifiers.

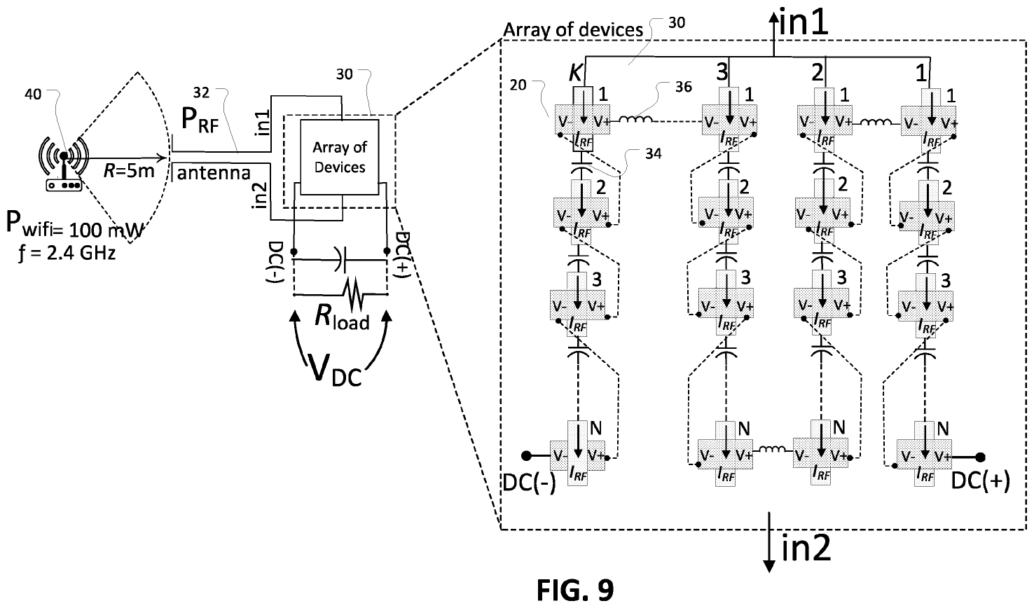

FIG. 10 shows a zero-bias sensitivity and comparison with existing devices.

FIG. 11 shows a comparison of figures-of-merit for a spin-orbit rectifier and fundamental limit in bridge rectifier.

FIG. 12 shows a comparison of spin-orbit rectifier efficiency with other technologies.

### DETAILED DESCRIPTION OF THE EMBODIMENTS

The embodiments propose a new rectifier/detector concept, simultaneously utilizing the Hall effect and spin-orbit-torque that is well matched to the low impedance of antennas. This is promising for general radio detection, and particularly for harvesting ambient weak radio signals, where conventional rectification fails to operate. As used here, the term “weak RF” means radio frequency signals having a power lower than 1 μW.

The embodiments inject RF current in a Hall material to generate a Hall voltage, and use the same RF current in a spin-orbit material to control a magnet. The magnet then applies a magnetic field to the Hall material leading to a rectification of the Hall voltage. The embodiments use a magnet with low anisotropy energy to make it sensitive to low RF currents.

The Hall Effect, and spin-orbit-torque are both proportional to current density, which improves inversely with device cross-sectional area, providing the largest signals at the nanoscale. Using existing materials, a single device can provide 200 μV DC from 500 nW of RF power. A series array of such devices that can efficiently provide 300 mV DC while matching the receiver antenna impedance. Such magnetic devices can rectify weak RF power at low voltage and low impedance where conventional semiconductor rectifiers fail.

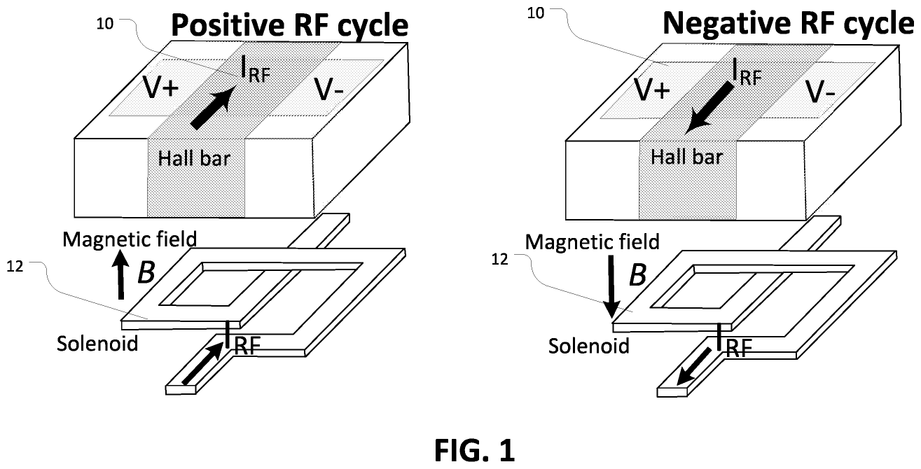

The Hall effect occurs when current-carrying conductor placed in a magnetic field (B) exhibits a voltage drop in the direction orthogonal to both the current and the B-field, due to the Hall effect. Interestingly, if one uses a fraction of the applied current to generate the B-field, for example using a solenoid underneath, as shown in FIG. 1, the B-field direction will follow the current and the Hall voltage will be unidirectional irrespective of the current direction. This leads to a rectification. This is the basic mechanism for rectification in the disclosed embodiments. However, a solenoid with large number of turns is required to produce a substantial B-field from a weak RF current, which is not desired for applications due to the size and the associated large inductance.

FIG. 1 shows the basic mechanism with a Hall material 10 and a solenoid 12 connected in parallel. A current divides equally between them I_{RF} and the magnetic field B in the solenoid follows the current direction. As mentioned above, the Hall voltage is unidirectional irrespective of the current direction.

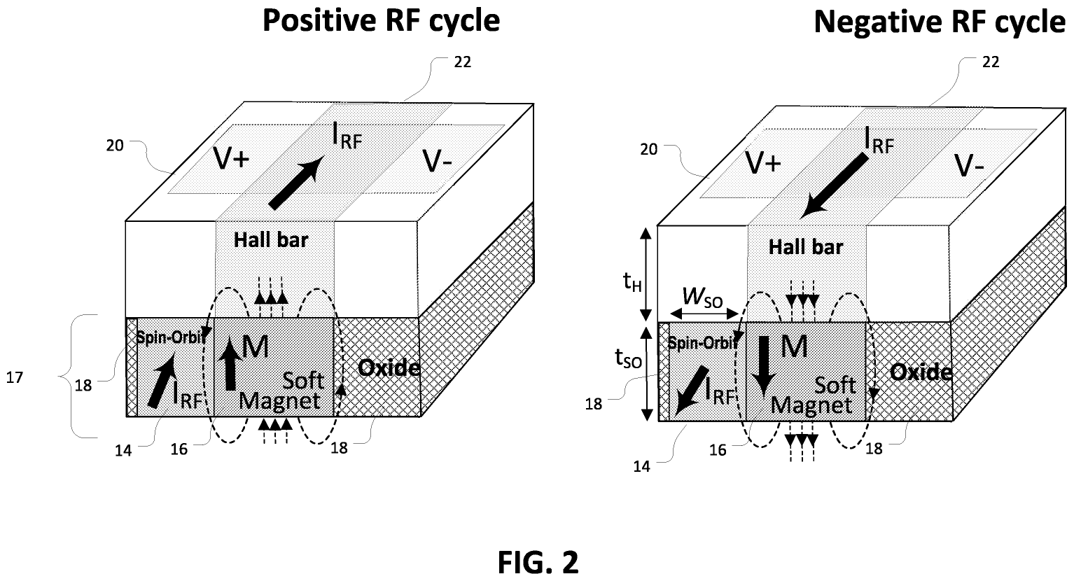

The embodiments here propose a spin-orbit rectifier structure 20 shown in FIG. 2, where the solenoid 12 in FIG. 1 is replaced with a bilayer 17 consisting of a spin-orbit (SO) material 14 and a soft ferromagnet (FM) 16, within an oxide layer 18 for insulation. The bilayer 17 may be referred to here as the spin-orbit layer, or the SO layer. The design of the device 20 is such that a RF current equally divides between the Hall layer 22 and the SO material 14. The FM magnetization (M) on average follows the fraction of the current flowing in the SO layer, provided that the current is sufficiently higher than a minimum value Iₘᵢₙ. The magnetization follows the current in the spin-orbit material 14 due to the spin-orbit torque and the magnet 16 applies a B-field on the Hall layer 22, resulting in a similar mechanism as in FIG. 1.

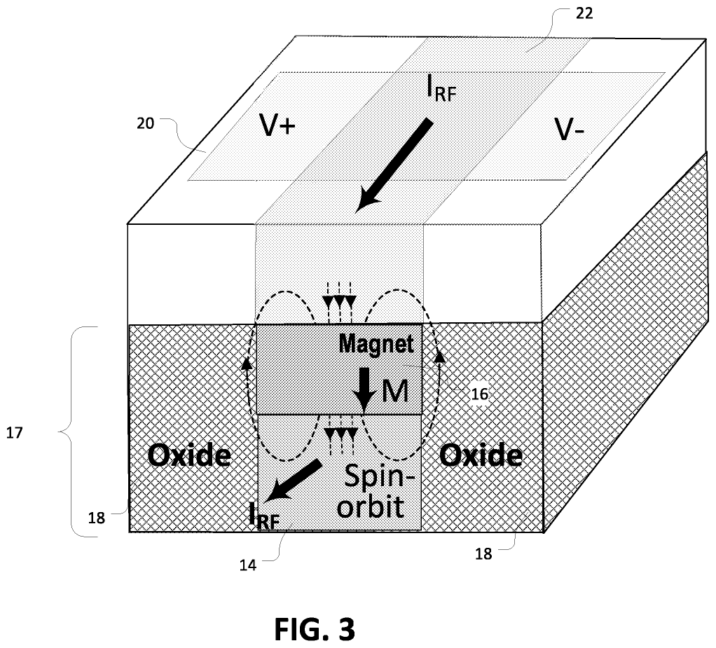

In an alternative embodiment, the SO bi-layer comprises the ferromagnet 16 stacked on the SO material 14 and arranged under the Hall layer. FIG. 3 shows an embodiment of such an arrangement. In both embodiments, the magnet layer is adjacent to the SO layer and the Hall layer, and oxide is on the outer surfaces of the SO layer.

The FM applies a B-field on the Hall material along the M-direction, leading to a rectified Hall voltage:

$${V}^{+} - {V}^{-} = ( \frac{{ρ}_{H}}{{t}_{H}} M ) {I}_{RF} \qquad ( 1 )$$

where ρ_{H} is the Hall resistivity, and t_{H} is the thickness of the Hall material, and M is the normalized magnetization along the easy-axis.

The minimum current (Iₘᵢₙ) for rectification is related to the spin-torque driven switching current which is given by the following expression for a single domain magnet:

$${I}_{min} = \frac{1}{{θ}_{SH}} \frac{{w}_{so}}{L} \frac{4 q}{h} {E}_{b} α , \qquad ( 2 )$$

where θ_{SH} is the spin Hall angle and wₛₒ is the SO layer width, L is the device width, α is the Gilbert damping, q is the electron charge and ℏ is the reduced Planck's constant.

The anisotropy energy, Eb, of the ferromagnet depends on the coercive field (H_{c}), the saturation magnetization (Mₛ), and the FM volume (v_{FM}). This may be represented by the relationship Eb=½ H_{c}Mₛ v_{FM}. In order to reduce Iₘᵢₙ, one wants an FM with low E_{b}, an SO with high θ_{SH}, and an FM-SO interface with low α. The stochastic-LLG (s-LLG) based stimulations take into account the stochastic behavior of the FM due to the thermal field.

Experimentally, Eb has been reduced by lowering the total magnetic moment (Mₛ×volume) or by tuning the FM thickness to optimize near the transition point between in-plane and perpendicular anisotropies or by using isotropic geometries. The embodiments consider a soft ferrite that exhibits a low H_{c} and a small FM volume to achieve a substantially low Eb. Such a FM with very low Eb can, in principle, switch stochastically between +1 and −1 due to the thermal noise, which is taken into account in the s-LLG equation-based simulations. A strong spin-orbit torque (SOT) can pin the magnetization to one of the states. A stochastic FM, on average, follows the current-induced SOT, and the average M follows the following relation:

$$〈 M 〉 = tanh ( \frac{{I}_{RF}}{{I}_{sat}} ) , \qquad ( 3 )$$

Where Iₛₐₜ is the current required to fully saturate the FM. In a completely stochastic FM driven by high thermal noise, Iₛₐₜ=Iₘᵢₙ with Eb 3/2 k_{B}T. Low anisotropy energy magnets can achieve a wide frequency bandwidth of operation, depending on the total magnetic moment in the FM and the angular momentum conservation. Low anisotropy energy as used here is ˜2 kT. A FM with Eb ranging from 0 to 10 kT, in principle, can be called a low anisotropy energy magnet.

The Hall 22 layer can be, but not limited to, InAs, GaAs, InGaAs, InSb, Ge, Si, etc., which are known to have large Hall coefficient due to smaller electron density. For the embodiment in FIG. 2, the spin-orbit material 14 can be any materials that exhibit an in-plane damping-like torque. For the embodiment in FIG. 2, the spin-orbit material 14 can be any materials that exhibit an out-of-plane damping-like torque or exhibits an antisymmetric Dzyaloshinskii-Moriya interaction (DMI) with the magnetic interface. The spin-orbit material 14 include but not limited to can be transition metals: Pt, Ta, Ir, W, etc., topological insulator materials: Bi₂Se₃, Bi₂Te₃, (BiₓSb₁₋ₓ)₂Te₃, Bi₂Te₂Se, BiSbTeSe₂, etc., topological semimetals: WTe₂, WSe₂, Cd₃As₂, etc., oxides e.g., SrIrO₃, SrRuO₃, LaAlO₃/SrTiO₃, etc. semiconductors: InAs, etc. The ferromagnetic material 16 should be a magnet with low anisotropy energy. Soft magnetic materials may include Sendust, CoZr, CoZrTa, CoNbZr, CoFe, FeCoB, Co, Fe, Fe—X—N, where X═Al, Ta, Co, Rh, Cr, Mo, Zr, Si, or Ti, CoFeNi, NiFe, etc., or soft ferrite materials e.g. MnZn, NiZn, etc., or CoFe₂O₄, oxidized CoFeB—O, CoAl—O, etc. “Sendust” refers to a magnetic metal powder the is typically 85% iron, 9& silicon, and 6% aluminum, and is generally sintered into a core. An oxide heterostructure like SrIrO₃/LSMO can serve as an efficient SO bi-layer as such bilayers show high spin-orbit torque and enhanced magnetism, compared to individual layers of SrIrO₃ and LSMO. The SrIrO₃/LSMO may comprise an epitaxially-grown layer. Furthermore, silicides such as FeₓSi₁₋ₓ, NiₓSi₁₋ₓ, CoₓSi₁₋ₓ, etc., where x represents % concentration, are also promising material to construct the SO bi-layer, where the concentration of the magnetic component, such as Fe, Ni, or Co, can define the magnetic layer and spin-orbit layer on the same silicon substrate. Usually when the magnetic component is >50% the layer becomes magnetic and below 50% the layer exhibits minimal magnetism but a strong spin-orbit torque. These may be referred to as silicides with varying magnetic concentration.

One embodiment device has a Hall layer, spin-orbit material, and FM each (100 nm)³. Another embodiment has the length, width and thickness of the Hall layer, the SO material and the FM layers as 100 nm, 100 nm, and 50 nm, respectively. The embodiments may use Bi₂Se₃ with resistivity ˜2 mΩ-cm and θ_{SH}=3.5 as the SO layer. The embodiments may use a soft ferrite as the FM which has an anisotropy energy E_{b}˜2 k_{B}T, calculated from its low coercivity H, =0.4 Oe, saturation field μ₀Mₛ=0.5 T and volume. This anisotropy energy, along with a Gilbert damping of 0.01 provides Iₘᵢₙ˜0.1 μA, calculated using Eq. (2). This example has neglected any effect of the demagnetizing field in the FM with low anisotropy energy and with a cubic geometry (no shape anisotropy). Presence of various non-idealities can increase Iₘᵢₙ from the calculated value. This example applies an RF current with rms (root mean square) value five times the threshold such as 0.5 μA in the SO, so that the FM can easily follow the RF current. The total RF current in a device is set to 1 μm.

The embodiment uses parameters for InAs as the Hall material and set the doping concentration to n˜10¹⁷ cm⁻³ in order to match the resistivity with the SO material such as 1/qnμₙ˜2 mΩWcm where the mobility is μₙ˜3×10⁴ cm²V⁻¹ s⁻¹. Since the resistivity of a ferrite is orders of magnitude higher than the Hall and SO materials, current in the FM is negligible. The total device resistance is 100Ω. Since equal amount of current flows in the SO and the Hall layers, the operating current for a single device can be as small as Iₒₚ=0.5 μA. The Hall coefficient is determined by the carrier concentration 1/qn˜62.5 cm³/C. Given that the soft ferrite can provide a saturation field around μ₀Mₛ=0.5 T, and assuming that the field lines in a thin Hall layer do not degrade much, one can calculate a Hall resistivity pH 3.75 mΩ-cm. This will produce a Hall voltage ˜375 μV DC in a single device from a 1 μA rms RF current in the Hall layer.

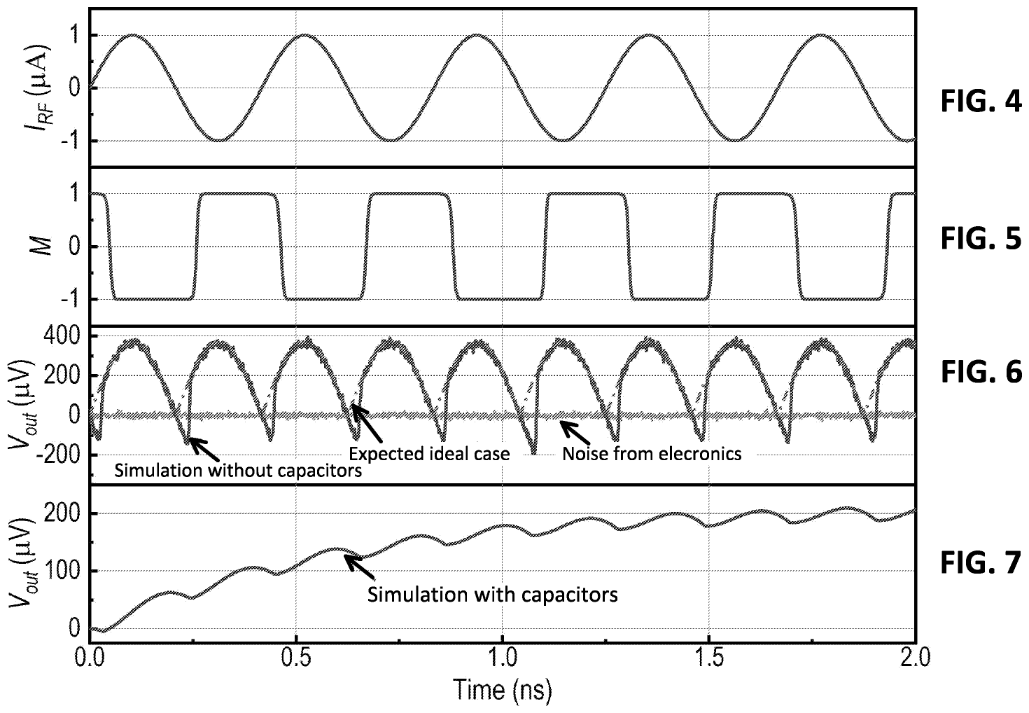

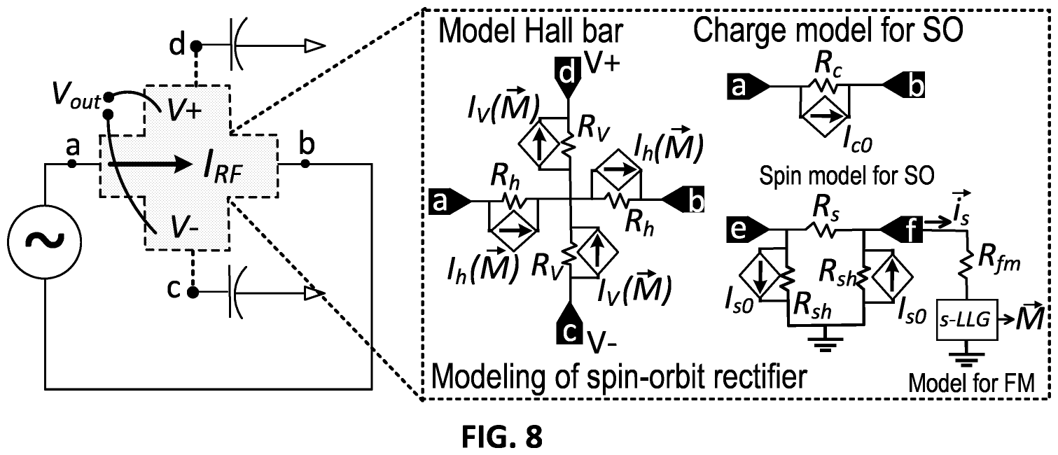

FIGS. 4-7 show the results of analysis of an embodiment of a rectifier using experimentally benchmarked SPICE models for the Hall, the SO, and the FM layers, as shown in FIG. 8, which considers both charge and spin transport phenomena within physics-based circuit models. The SPICE simulations consider thermal noise in both the electronic circuit and within the low anisotropy energy magnet. The simulations apply I_{RF}=I₀ sin(2πft) along the AC leg of the Hall bar with the amplitude I₀=1 μA and frequency f=2.4 GHz shown in FIG. 4. The operation of the proposed rectifier does not depend on the shape of the signal and will efficiently convert an alternating signal to a DC signal, as long as the current amplitude is sufficiently greater than Iₘᵢₙ. The current generates non-equilibrium spins in the SO material, which applies SOT to the FM. The magnetization dynamics under the SOT was calculated using the s-LLG equation implemented as a SPICE model. Both the field-like and damping-like torques can be present; however, damping-like torque generated by the non-equilibrium spin current is the dominant component in the material considered here. Field-like torque in the device arises from a current-induced Oersted field, which is very small, but taken into account within our s-LLG simulations.

The magnetization of the FM with low-anisotropy energy nicely follows the IRF, due to the strong SOT, as shown in FIG. 5. The FM applies a B-field on the Hall layer, which in conjunction with the fraction of the IF flowing in the Hall layer yields a Hall voltage response (Vₒᵤₜ) as a function of time (t), similar to a full-wave rectifier, as shown in FIG. 6. Note that Vₒᵤₜ, exhibits negative peaks when I_{RF} changes the sign, which arises due to Iₘᵢₙ and switching/response time of the FM. This causes Vₒᵤₜ, to deviate from the expected ideal case where Vₒᵤₜ∝|I_{RF}|, shown in FIG. 6, leading to a lowering of the DC voltage from the ideal case. Also, note that the size of the negative peaks varies in the s-LLG simulations due to the stochastic nature of the FM driven by thermal noise. However, the area of the positive regions is much larger compared to the negative region, indicating an average DC, which can charge up a capacitor to ˜210 μV, as shown in FIG. 7. Vou, in FIG. 6 is noisy due to the presence of thermal noise in the circuit. Such noisy behavior is not visible when a capacitor is connected at the output, as in FIG. 7.

One can further enhance the DC voltage strength for a given RF power by connecting multiple devices in series in an array while matching the array impedance with the antenna. For calculation, one can consider a WiFi router positioned 5 meters from the array as the RF source as in FIG. 8, which transmits P_{WiFi}=100 mW at frequency f=2.4 GHz, and wavelength ˜12.5 cm. The received RF power by the antenna at R=5 m is calculated using the Friis equation as P_{RF}≈(λ/4πR)² P_{WiFi}˜500 nW, which can 50 μA rms, if the array impedance is matched to the antenna at 50Ω. Here, the process has assumed isotropic antennas with unity gain.

The number of parallel branches in the array can be K=√2×50 μA/I_{RF}≈71. To match the array impedance to the antenna impedance (50Ω), each of the parallel branches can have N devices with resistance R_{dev} in series, where N×R_{dev}/K=50Ω. Here, N≈18 using R_{dev}=200Ω. The DC voltage can be enhanced by ˜N×K times by adding the DC paths of all the devices in series. In this example, if one were to add all the devices in series as shown in FIG. 8, the maximum rectified Hall voltage will be ˜480 mV from the same RF power of 500 nW, which considering the nonidealities can provide a DC voltage of ˜300 mV. One can connect two consecutive devices using a capacitor (˜10 pF) to reduce the leakage of the generated DC within the series-connected devices. To avoid an AC leakage through the DC path between two consecutive parallel branches, one can connect the DC paths using an inductor, which will act as a short circuit for the DC signal. The capacitors and inductors will make the area of the array larger, roughly on the order of ˜2 mm² for the present embodiments.

The inductor and capacitor dimensions are such that their reactances cancel out, and the SOT rectifiers in the array receive the maximum power from the antenna. The AC path of the SOT rectifier behaves like a linear resistor and the device does not contain any internal space charge regions like conventional semiconductor devices. However, parasitics arising from interconnects and contacts can make the impedance matching challenging. Other electrical structures with the same characteristics may be used. To differentiate the two types of electrical connections, the paths between devices in parallel branches connected by inductors from the connections through capacitors in each branch, the discussion may refer to inductor connections as “branch electrical connections,” and to the capacitor connections as “device connections.”

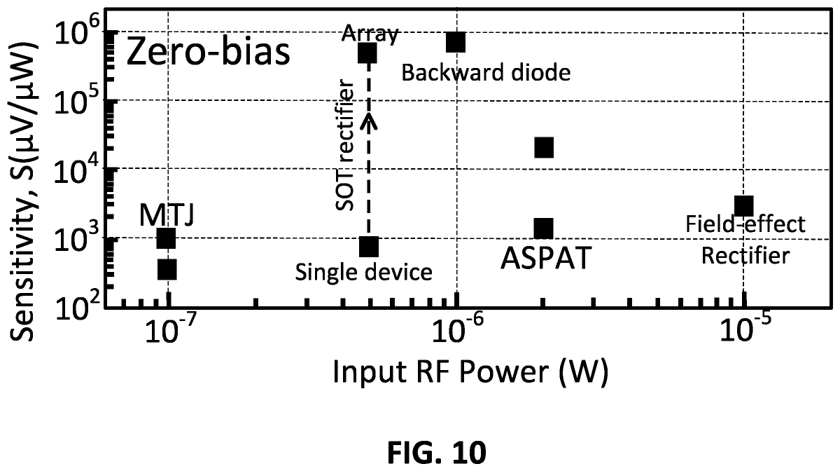

The open circuit output DC voltage for a given input RF power, such as S=Vₒᵤₜ/P_{RF}, is defined as the sensitivity of the RF detector. Various semiconductor diodes can offer high zero-bias sensitivity, on the order of ˜10⁸ μV/μW from an input power of ˜1 μW. Recently, magnetic tunnel junction (MTJ)-based diodes reported very high sensitivity, on the order of ˜10⁵ μV/μW from 100 nW. However, either an external magnetic or an electric bias is used to enhance the sensitivity of MTJ diodes and zero-bias sensitivity is on the order of 10²˜10³. A single SOT rectifier can provide a zero-bias sensitivity of 750 μV/μW and an optimized array can provide 4.8×10⁵ μV/μW, from an input RF power in the range of 500 nW, as shown in FIG. 10. The region 10 shows the range where conventional technologies have their efficiencies. Such a high zero-bias sensitivity can result in a low noise equivalent power (NEP) given by

$$NEP = \frac{\sqrt{4 {k}_{B} {TR}_{dev}}}{S} ,$$

where k_{B} is the Boltzmann constant and T is the temperature. For a single SOT rectifier, the expected noise-equivalent power is approximately 2.4 μW/√Hz (calculated using R_{dev} 400=Ω). The array is matched at R^{dev}=50Ω and the expected NEP is approximately 1.9 fW/√Hz.

The curvature coefficient of a detector is defined as:

$$γ = ( \frac{{d}^{2} I}{{dV}^{2}} ) / ( \frac{dI}{dV} ) . \qquad ( 4 )$$

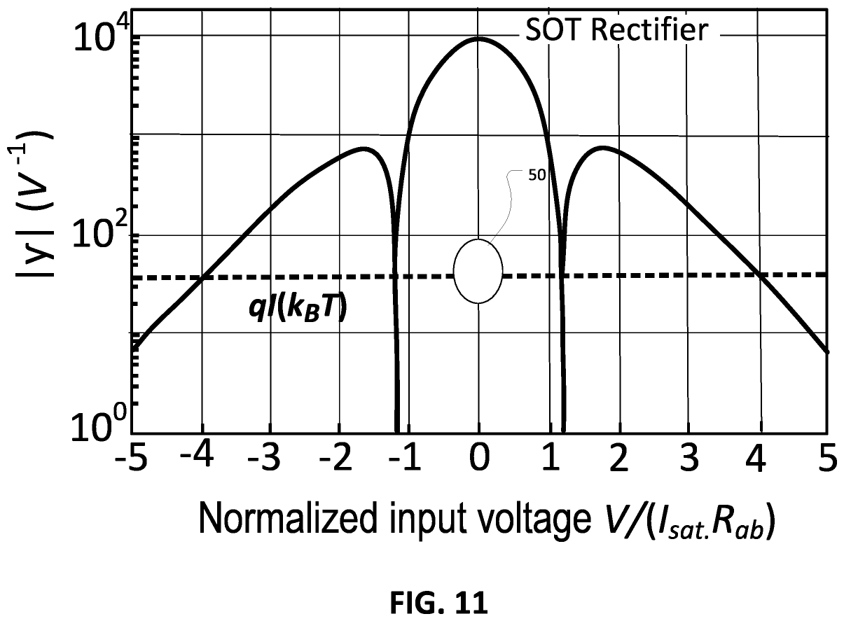

For a conventional diode with I=I_{S}[exp(qV/(mk_{B}T))−1], resulting in γ=q/(mk_{B}T) where m is the diode nonideality factor. For Schottky diodes, the theoretical limit is γ=q/(mk_{B}T), which is 38.65V⁻¹ at T=300K and m=1. Backward tunnel diodes have exhibited a γ higher than this theoretical limit, on the order of 50 to 70 V⁻¹ at zero bias, roughly two times higher than the theoretical limit in the Schottky diodes. The proposed SOT rectifier can exhibit high zero bias γ, on the order of 10⁴ V⁻¹, as shown in FIG. 11, which is roughly 259 times higher than the theoretical limit in the Schottky diodes. For very large input current (I_{RF}>>Iₛₐₜ), the DC voltage of a SOT rectifier is proportional to the current, Vₒᵤₜ∝|I_{RF}|. For a smaller input current, the current-voltage relation exhibits high curvature leading to a high γ. This feature is promising for general radio detection applications from weak signals. For a SOT rectifier, I=Vₒᵤₜ/R_{cd} is the output DC current and V=I_{RF}R_{ab} is the input AC voltage in Eq. (4), where R_{ab} and R_{cd} are the resistances between nodes a and b and c and d, respectively, as in FIG. 8.

The efficiency of a rectifier is determined by the maximum DC power, P_{DCmax}, produced from a given RF power, P_{RF}, as

$$η = \frac{{P}_{DCmax}}{{P}_{RF}} = \frac{\frac{1}{4} {V}_{cd}^{2} / {R}_{cd}}{{I}_{ab}^{2} {R}_{ab}} \qquad ( 5 )$$

where V_{cd} and R_{cd} are the open circuit voltage and source resistance between nodes c and d as in FIG. 8. I_{ab}=I₀/√2 is the rms value of I_{RF} and R_{ab} is the resistance between a and b nodes. Here, R_{ab}=ρL/Wt_{d} is the longitudinal resistance, L and Ware the device length and width, and t_{d}=tₛₒ+t_{H} is the total device thickness. From this, one can extract equivalent R_{cd}=2Rᵥ+2(Rᵥ)²/Rh from the model in FIG. 8, using wye-delta transformation when a and b nodes are short circuited. Here, Rᵥ=ρL/2Lt_{H} and Rₕ=ρL/2Wt_{H} are the vertical and horizontal resistors in the model. The process uses Eq. (1) to estimate

$${V}_{cd} = {\int }_{0}^{T} ( \frac{{ρ}_{H}}{{t}_{H}} ) \vert {I}_{RF} \vert dt = \frac{2}{π} ( \frac{{ρ}_{H}}{{t}_{H}} ) {I}_{0} .$$

Equation (5) becomes:

$$η = {( \frac{\sqrt{2} {ρ}_{H}}{πρ} )}^{2} \frac{{t}_{d}}{{t}_{H}} \frac{1}{1 + {W}^{2} / {L}^{2}} .$$

In this example, the device was designed such that it provides a high efficiency while matching the antenna impedance, and t_{d}≈2t_{H} and W≈L, which in Eq. (5) gives

$$η = {( \frac{\sqrt{2}}{π} \frac{{ρ}_{H}}{ρ} )}^{2} .$$

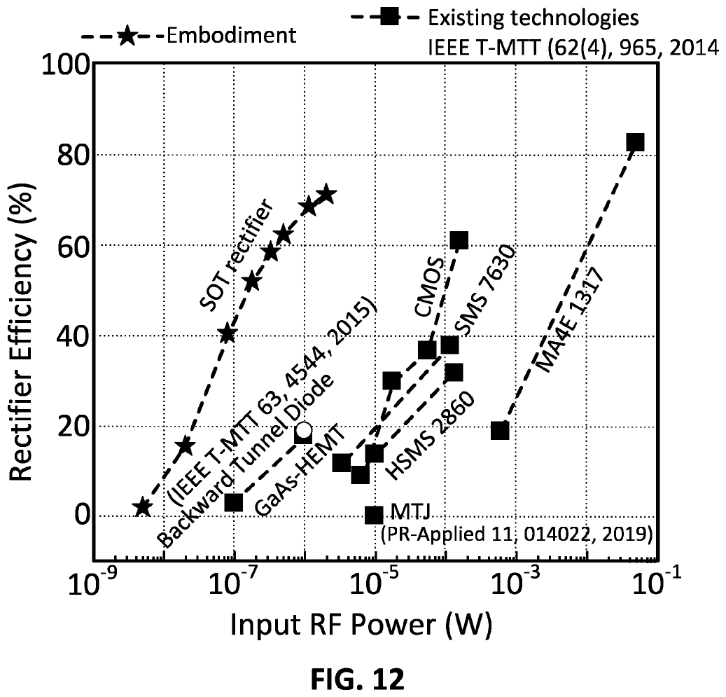

This results in an efficiency value of ≈71% for the materials and device parameters under consideration, which is observed for ≥500 nW RF power. The efficiency degrades for lower input RF power. FIG. 12 shows a comparison of the efficiency of the SOT rectifier with the conventional semiconductor and magnetic technologies.

In conclusion, the embodiments provide a nanoscale rectifier concept that is promising for general radio detection and, particularly, for harvesting ambient weak radio signals, where conventional rectification fails to operate. The discussion shows an analysis of a single device in SPICE using existing materials parameters and show that it can provide 200 ρV DC from 500 nW of RF power. A series array of such devices can efficiently enhance the DC voltage to 300 mV while matching the receiver antenna impedance. The expected efficiency is ≈71% at such a low RF power, which makes this nanoscale device promising for powering of the emerging applications such as wearable electronics, self-powered and wireless-powered sensors, and implants. Moreover, the nanoscale rectifier promises to operate at 259 times lower than the thermal voltage limit in the conventional semiconductor-based rectifiers.

It will be appreciated that variants of the above-disclosed and other features and functions, or alternatives thereof, may be combined into many other different systems or applications. Various presently unforeseen or unanticipated alternatives, modifications, variations, or improvements therein may be subsequently made by those skilled in the art which are also intended to be encompassed by the embodiments.

1. A rectifier device, comprising:
a Hall layer comprising a layer of a Hall material; and
a spin-orbit layer adjacent the Hall layer, the spin-orbit layer comprising:
a spin-orbit material having a first surface and a second surface;
a ferromagnet adjacent the spin-orbit material; and
oxide on the first and second surfaces of the spin-orbit layer.

2. The device as claimed in claim 1, wherein the Hall material is one selected from the group consisting of: InAs, GaAs, InGaAs, InSb, Ge, and Si.

3. The device as claimed in claim 1, wherein the spin-orbit material comprises one of a transition metal, a topological insulator material, a topological semimetal, a semiconductor, an oxide heterostructure, or a silicide with varying magnetic concentration.

4. The device as claimed in claim 3, wherein the spin-orbit material is one selected from the group consisting of: Pt, Ta, Ir, W, Bi₂Se₃, Bi₂Te₃, (BiₓSb₁₋ₓ)₂Te₃, Bi₂Te₂Se, BiSbTeSe₂, WTe₂, WSe₂, Cd₃As₂, InAs. SrIrO₃, SrRuO₃, LaAlO₃/SrTiO₃, FeₓSi₁₋ₓ, NiₓSi₁₋ₓ, and COₓSi₁₋ₓ.

5. The device as claimed in claim 1 wherein the spin-orbit layer comprises an epitaxially grown SrIrO₃/LSMO bi-layer.

6. The device as claimed in claim 1, wherein the ferromagnet has low anisotropy energy.

7. The device as claimed in claim 1, wherein the ferromagnet has anisotropy energy in the range of 0-10 k_{B}T.

8. The device as claimed in claim 1, wherein the ferromagnet comprises one of a soft magnetic material or a soft ferrite material.

9. The device as claimed in claim 1, wherein the ferromagnet comprises one selected from the group consisting of: Sendust, Co, Fe, CoZr, CoZrTa, CoNbZr, CoFe, FeCoB, Fe—X—N, where X═Al, Ta, Co, Rh, Cr, Mo, Zr, Si, or Ti, CoFeNi, NiFe, MnZn, NiZn, CoFe₂O₄, oxidized CoFeB—O, and oxidized CoAl—O.

10. The device as claimed in claim 1, wherein the Hall layer, spin-orbit material and ferromagnet each measure 100 nm³.

11. The device as claimed in claim 1, wherein the spin-orbit material comprises Bi₂Se₃ with resistivity of 2 mΩ-cm and θ_{SH}=3.5, the Hall layer comprises InGaAs with a doping concentration of n=10¹⁷ cm⁻³, and the ferromagnet comprises a soft ferrite material.

12. A rectifying system, comprising:
an array of rectifying devices having a number, K, of parallel branches, each branch having N devices, each rectifying device comprising:
a Hall layer comprising a layer of a Hall material;
a spin-orbit layer adjacent the Hall layer, the spin-orbit layer comprising:
a spin-orbit material;
a ferromagnet adjacent the spin-orbit material; and
oxide on outer surfaces of the spin-orbit layer;
branch electrical connections between corresponding devices in each of the parallel branches; and
device electrical connection between devices in each parallel branch.

13. The rectifying system as claimed in claim 12, further comprising an antenna electrically connected to the array of rectifying devices.

14. The rectifying system as claimed in claim 13, wherein an impedance of the antenna matches an impedance of the array.

15. The rectifying system as claimed in claim 12, wherein each of the branch electrical connections along a DC path includes an inductor.

16. The rectifying system as claimed in claim 12, wherein each of the device electrical connections along an AC path includes a capacitor.

17. The rectifying system as claimed in 12, wherein each branch of the electrical connections includes an inductor, and each of the device electrical connections includes a capacitor.

18. The rectifying system as claimed in claim 17, wherein the inductors and capacitors have dimensions such that reactances of the inductors and capacitors cancel out.
